(19) United States
(12) Patent Application Publication
(10) Pub. No.: US 2016/0244665 A1
(43) Pub. Date: Aug. 25, 2016

(54) PHOSPHORS

(71) Applicant: MERCK PATENT GMBH, Darmstadt (DE)

(72) Inventors: Tim VOSGROENE, Ober-Ramstadt (DE); Holger WINKLER, Darmstadt (DE); Ralf PETRY, Griesheim (DE); Christof HAMPEL, Frankfurt am Main (DE); Andreas BENKER, Lautertal (DE)

(73) Assignee: MERCK PATENT GMBH, Darmstadt (DE)

(21) Appl. No.: 15/031,050

(22) PCT Filed: Sep. 23, 2014
(86) PCT No.: PCT/EP2014/002573

§ 371 Date: Apr. 21, 2016

(30) Foreign Application Priority Data
Oct. 21, 2013 (EP) 13005028.9

(51) Int. Cl. C09K 11/77; H01L 33/50; H01L 33/32; H05B 33/14

(52) U.S. Cl. CPC C09K 11/7774; H05B 33/14; H01L 33/502; H01L 33/32

(57) ABSTRACT

The present invention relates to cerium-doped garnet phosphors. The present invention furthermore relates to a process for the preparation of cerium-doped garnet phosphors, and to the use of these garnet phosphors as conversion phosphors. The present invention furthermore relates to a light-emitting device which contains cerium-doped garnet phosphors according to the invention.

The present invention relates to cerium-doped garnet phosphors. The present invention furthermore relates to a process for the preparation of cerium-doped garnet phosphors, and to the use of these garnet phosphors as conversion phosphors. The present invention furthermore relates to a light-emitting device which contains cerium-doped garnet phosphors according to the invention.

Inorganic fluorescent powders which can be excited in the blue and/or UV spectral region are constantly increasing in importance as conversion phosphors for phosphor-converted LEDs, pc-LEDs for short. Many conversion phosphor material systems are now known, such as, for example, alkaline-earth metal orthosilicates, thiogallates, nitrides and garnets, each of which are doped with Ce³⁺ or Eu²⁺. The last-mentioned garnet phosphors in particular, which have the general formula M₃Al₅O₁₂:Ce³⁺, in which M stands for Y, Lu, Tb or Gd, have intense absorption in the blue spectral region, which is converted very efficiently into yellow (YAG:Ce) or yellow-green (LuAG:Ce) emission. For this reason and owing to their high chemical stability, these materials are widespread.

The synthesis of garnet phosphors is carried out, in particular, as a solid-state synthesis from the oxides, i.e., for example, from Lu₂O₃, Al₂O₃ and Eu₂O₃. Furthermore, synthesis processes from solution are also known. In these, fluxing agents are usually employed for the synthesis. These have various jobs; inter alia, they facilitate lower reaction temperatures and/or accelerated crystal growth, or they suppress the formation of foreign phases. It is also possible for the fluxing agent to be incorporated, at least in traces, into the resultant garnet phosphor. Various substances, in particular BaF₂ and other fluorides, are known as fluxing agents in the synthesis of garnet phosphors.

A positive effect of these fluxing agents on the luminescence properties of the resultant garnet phosphor is not evident. Furthermore, in spite of the use of the above-mentioned fluxing agents, the requisite reaction temperature in the synthesis is still very high and is up to about 1800° C. This makes considerable demands of the furnaces and equipment used, such as, for example, crucibles. Furthermore, the process is very energy-intensive owing to the high temperatures.

U.S. Pat. No. 6,409,938 describes the synthesis of YAG:Ce and other garnets using AlF₃ as fluxing agent. Higher quantum efficiency is thereby achieved. In addition, a less strongly reducing atmosphere is sufficient for the reaction, which simplifies the reaction management. The resultant garnet phosphor may also comprise a small amount of fluoride from the fluxing agent. Both solid-state processes and also wet-chemical processes are described. The reaction temperature used is 1500° C.

In general, the fluoride fluxing agents described in the prior art are corrosive and are therefore difficult to handle on an industrial scale.

In all these processes, it would be desirable if the garnet phosphors produced were to have even higher quantum efficiency. It would furthermore be desirable if even lower reaction temperatures were sufficient in the synthesis. In addition, it would be desirable to be able to avoid the use of corrosive fluorides as fluxing agents, which would result in simplified industrial performance of the synthesis.

The object of the present invention was thus to provide a process for the synthesis of garnet phosphors by means of which the quantum efficiency of the garnets can be increased and/or in which a lower reaction temperature than in accordance with the prior art is sufficient. A further object of the present invention was the provision of a process for the synthesis of garnet phosphors which avoids the use of a fluoride-containing fluxing agent, but nevertheless gives good results. A further object of the present invention is the provision of garnet phosphors which have higher quantum efficiency compared with garnet phosphors in accordance with the prior art.

Surprisingly, it has been found that this object is achieved by preparing the garnet phosphor by a wet-chemical process, where the fluxing agent employed is a mixture of an alkaline-earth metal halide and a silicon dioxide suspension. The present invention therefore furthermore relates to garnet phosphors which are obtainable by a process of this type.

The invention therefore relates to a compound of the formula (1),

(Lu₁₋ᵥM′ᵥ)_{3-x-z}(EA)_{z}(Al_{1-y}Ga_{y})_{5-z}(Si_{1-w}Ge_{w})_{z}O₁₂:Ce³⁺ₓ formula (1)

where the following applies to the symbols and indices used:
M′ is Y, Tb, Gd or a mixture of these metals;
EA is Ca, Sr, Ba or a mixture of these metals;
0<x<0.50;
0≦y≦0.40;
0.01≦z≦0.5;
   0≦w≦1;
   0≦v<1.

In a preferred embodiment of the invention, v=0. This is thus preferably a compound of the following formula (1a),

Lu_{3-x-z}(EA)_{z}(Al_{1-y}Ga_{y})_{5-z}(Si_{1-w}Ge_{w})_{z}O₁₂:Ce³⁺ₓ formula (1a)

where the symbols and indices used have the meanings given above.

In a further preferred embodiment of the invention, y=0. This is thus preferably a compound of the following formula (1b),

(Lu₁₋ᵥM′ᵥ)_{3-x-z}(EA)_{z}Al_{5-z}(Si_{1-w}Ge_{w})_{z}O₁₂:Ce³⁺ₓ formula (1b)

where the symbols and indices used have the meanings given above.

In still a further preferred embodiment of the invention, w=0. This is thus preferably a compound of the following formula (1c),

(Lu₁₋ᵥM′ᵥ)_{3-x-z}(EA)_{z}(Al_{1-y}Ga_{y})_{5-z}Si_{z}O₁₂:Ce³⁺ₓ formula (1c)

where the symbols and indices used have the meanings given above.

The preferences mentioned above particularly preferably occur simultaneously. These are thus particularly preferably compounds of the following formulae (2a) and (2b),

(Lu₁₋ᵥM′ᵥ)_{3-x-z}(EA)_{z}Al_{5-z}Si_{z}O₁₂:Ce³⁺ₓ formula (2a)

Lu_{3-x-z}(EA)_{z}Al_{5-z}Si_{z}O₁₂:Ce³⁺ₓ formula (2b)

where the symbols and indices used have the meanings given above and v in formula (2a) is preferably >0.

In a preferred embodiment of the above-mentioned compounds, EA is selected from Sr and/or Ba, particularly preferably Sr.

In a further preferred embodiment of the invention, the following applies to x, i.e. the proportion of Ce: 0.01≦x≦0.15.

In still a further preferred embodiment of the invention, the following applies to z, i.e. the proportion of the alkaline-earth metal and of silicon or germanium: 0.01≦z≦0.25, particularly preferably 0.01≦z≦0.15, in particular 0.05≦z≦0.10.

In still a further embodiment, the compounds according to the invention may be coated. All coating methods as are known to the person skilled in the art in accordance with the prior art and are used for phosphors are suitable for this purpose. Suitable materials for the coating are, in particular, metal oxides, such as Al₂O₃, TiO₂, ZrO₂ or ZnO₂, and nitrides, such as AlN, as well as SiO₂.

The coating here can be carried out, for example, by fluidised-bed methods. Further suitable coating methods are known from JP 04-304290, WO 91/10715, WO 99/27033, US 2007/0298250, WO 2009/065480 and WO 2010/075908.

The present invention furthermore relates to a process for the preparation of a cerium-doped garnet, characterised in that the process is carried out via a precursor prepared by wet-chemical methods, and a silicon- or germanium-containing compound and an alkaline-earth metal halide are added.

A cerium-doped garnet in the sense of the present invention is a compound of the following formula (3),

M₃₋ₓ(Al_{1-y}Ga_{y})₅O₁₂:Ce³⁺ₓ formula (3)

where the following applies to the symbols and indices used:
M is Lu, Y, Tb, Gd or a mixture of these metals;
0<x<0.50;
0≦y≦0.40;
some of the ions M here may also be replaced by an alkaline-earth metal selected from Mg, Ca, Sr and/or Ba, and at the same time an equal proportion of Al or Ga may be replaced by Si or Ge.

In a preferred embodiment of the invention, the cerium-doped garnet is a compound of the following formula (4),

M_{3-x-z}(EA)_{z}(Al_{1-y}Ga_{y})_{5-z}(Si_{1-w}Ge_{w})_{z}O₁₂:Ce³⁺ₓ formula (4)

where M, x and y have the meanings given above and the following applies to the other symbols and indices used:
EA is Mg, Ca, Sr, Ba or a mixture of these metals;
0.01≦z≦0.5; 0≦w≦1.

Preferred embodiments of the compounds of the formula (4) are the compounds of the formulae (1), (1a), (1b), (1c) and (2) shown above.

In a preferred embodiment of the invention, the process includes the preparation of a silicon dioxide suspension. Suitable starting materials for this purpose are all silicon-containing compounds which hydrolyse to give silicon dioxide. Suitable silicon-containing starting materials are tetraalkyl orthosilicates, where the alkyl groups have, identically or differently on each occurrence, 1 to 10 C atoms, preferably, identically or differently on each occurrence, 1 to 4 C atoms, in particular tetramethyl, tetraethyl, tetra-n-propyl, tetraisopropyl and tetrabutyl orthosilicate, as well as silicon halides, in particular SiCl₄ and SiBr₄. Particular preference is given to tetramethyl orthosilicate (TMOS) and tetraethyl orthosilicate (TEOS).

Analogously, the process may include the preparation of a germanium dioxide suspension. Suitable starting materials for this purpose are all germanium-containing compounds which hydrolyse to give germanium dioxide. Suitable germanium-containing starting materials are tetraalkyl orthogermanates, where the alkyl groups have, identically or differently on each occurrence, 1 to 10 C atoms, preferably, identically or differently on each occurrence, 1 to 4 C atoms, in particular tetramethyl, tetraethyl, tetra-n-propyl, tetraisopropyl and tetrabutyl orthogermanate, as well as germanium halides, in particular GeCl₄ and GeBr₄. Particular preference is given to tetramethyl orthogermanate and tetraethyl orthogermanate.

These compounds serve as silicon dioxide or germanium dioxide precursors for the preparation of colloidal sol-gel systems. Since TMOS, TEOS and the corresponding Ge compounds are substantially insoluble in water, the reaction medium used is preferably a mixture of an alcohol, preferably having 1 to 4 C atoms, particularly preferably methanol or ethanol, and water. The hydrolysis of these compounds to give orthosilicic acid H₄SiO₄ or to give H₄GeO₄ and ethanol or methanol proceeds very slowly in neutral water. The H₄SiO₄ or H₄GeO₄ formed decomposes further to silicon dioxide or germanium dioxide respectively through the formation of Si—O—Si or Ge—O—Ge bonds and release of water. The hydrolysis takes place considerably more quickly in acidic or alkaline medium, since both considerably catalyse the reaction. In a preferred embodiment of the invention, the preparation of the SiO₂ or GeO₂ suspension is therefore carried out in alkaline solution, in particular in an ammoniacal solution. It is particularly preferred for the SiO₂ or GeO₂ suspension to be neutralised after its preparation, in particular by addition of acid, for example hydrochloric acid.

In accordance with the invention, the process is furthermore carried out with addition of an alkaline-earth metal halide. The alkaline-earth metal here is selected from Mg, Ca, Sr and/or Ba, preferably Ca, Sr and/or Ba, particularly preferably Sr and/or Ba and in particular Sr. The halide ion is preferably not fluoride owing to the corrosiveness of fluoride and the more-complex reaction management thus necessary. The halide ion is preferably chloride or bromide, in particular chloride. Preference is thus given to the addition of CaCl₂, SrCl₂ and/or BaCl₂, particularly preferably SrCl₂ and/or BaCl₂ and in particular SrCl₂.

In an embodiment of the process according to the invention, a solution of one or more salts containing M, a cerium salt, an aluminium salt, an alkaline-earth metal salt and optionally a gallium salt is prepared. The solution is preferably prepared in water.

Alternatively, it is possible to prepare a plurality of solutions, each of which contains only one or some of the metals.

The ratio of M, Ce, Al, EA, Si or Ge and optionally Ga in the solutions and suspensions is determined from the desired ratio of these elements in the product. The following preferably applies here to the proportion of EA and Si or Ge: 0.01≦z≦0.25, particularly preferably 0.01≦z≦0.15 and in particular 0.05≦z≦0.1.

Suitable salts are any desired salts of the corresponding metals, provided they are sufficiently soluble in water.

Suitable salts of the metals M, Ce, Al and optionally Ga are the halides, in particular chlorides, bromides and iodides, nitrates and carbonates, optionally in the form of the corresponding hydrates. Preference is given to the chlorides MCl₃, CeCl₃ and AlCl₃, and, for Ga, in particular also Ga(NO₃)₃, in each case in the form of the hydrates.

The solution described above or the solutions containing M, Ce, Al, EA and optionally Ga is (are) combined with the SiO₂ or GeO₂ suspension. A precipitation reagent, for example ammonium hydrogencarbonate solution, is preferably added to the SiO₂ or GeO₂ suspension here. This serves for precipitation of the ions in the form of the carbonates. It is preferred here for the solution or the solutions containing M, Ce, Al, EA and optionally Ga to be added to the SiO₂ or GeO₂ suspension, where this addition preferably takes place slowly, for example dropwise. Since, in particular, the halides, if the metals are employed in the form of the halides, for example chlorides, are acidic, it may be sensible for the mixture to be neutralised or rendered basic during the reaction, for example by addition of ammonia solution.

The mixture formed is stirred, for example for a period of 1 minute to 24 h, preferably 10 minutes to 10 h, particularly preferably 15 minutes to 1 h. A solid forms during this time.

In a next process step, the solid is separated off, for example by filtration, with or without suction, and dried. The drying of the solid can be carried out in vacuo and/or at elevated temperature, preferably at 60-200° C., particularly preferably at 100-150° C.

The precursor obtained in this way is preferably converted into the product by two calcination steps. The first calcination step here is preferably carried out at a temperature of 800 to 1400° C., particularly preferably 1000 to 1200° C. This first calcination step is preferably carried out in air.

The second calcination step is preferably carried out at a temperature of 1000 to 1600° C., particularly preferably 1200 to 1500° C., very particularly preferably 1200 to 1400° C.

The second calcination step here is preferably carried out under non-oxidising conditions, i.e. under substantially or completely oxygen-free conditions, in particular under reducing conditions. Non-oxidising conditions are taken to mean any conceivable non-oxidising atmospheres, in particular substantially oxygen-free atmospheres, i.e. an atmosphere whose maximum oxygen content is <100 ppm, in particular <10 ppm. A non-oxidising atmosphere can be produced, for example, through the use of protective gas, in particular nitrogen or argon. A preferred non-oxidising atmosphere is a reducing atmosphere. The reducing atmosphere is defined as comprising a gas having a reducing action. What gases have a reducing action is known to the person skilled in the art. Examples of suitable reducing gases are hydrogen, carbon monoxide, ammonia or ethylene, preferably hydrogen, where these gases may also be mixed with other non-oxidising gases. The reducing atmosphere is particularly preferably produced by a mixture of nitrogen or argon and hydrogen, preferably in the ratio H₂:N₂ or H₂:Ar of 5:95 to 50:50, preferably about 10:90, in each case based on the volume.

It may be preferred to cool and comminute the pre-calcined product, for example by grinding, between the first and second calcination steps.

The reaction duration of the first and second calcination steps is in each case, independently of one another, preferably in the range from 1 to 18 h, particularly preferably in the range from 3 to 8 h.

The calcination is preferably in each case carried out by introducing the mixtures obtained into a high-temperature furnace, for example in a vessel, for example made from boron nitride, Al₂O₃ or ceramic. The high-temperature furnace is, for example, a tubular furnace, which contains a molybdenum foil tray.

After the calcination, the product is usually worked up by grinding, washing and/or sieving. The washing can be carried out, for example, with water and/or an acid, such as, for example, hydrochloric acid or nitric acid.

Surprisingly, it has been found that the quantum efficiency of the product obtained is higher than the quantum efficiency of comparable compounds prepared by another process or with addition of another fluxing agent, without other properties of the phosphor being impaired.

The present invention furthermore relates to a compound which is obtainable by the process according to the invention. The compound prepared by the process according to the invention differs from compounds of the same or similar composition prepared in accordance with the prior art in that it has higher emission efficiency. Owing to the complex structure of the compound according to the invention, the compound according to the invention cannot be unambiguously characterised by structural features. However, it can be unambiguously differentiated from compounds known from the prior art in that it has higher radiation-induced emission efficiency or intensity and possibly a colour shift of the emission maximum. Characterisation of the compound according to the invention by the steps of the preparation process according to the invention is therefore justified.

The present invention furthermore relates to the use of a compound according to the invention, in particular a compound of the formula (1), (1a), (1b), (1c), (2), (2a) or (2b), as phosphor, in particular as conversion phosphor.

The present invention furthermore relates to an emission-converting material comprising the compound according to the invention. The emission-converting material may consist of the compound according to the invention and would in this case be equivalent to the term “conversion phosphor”.

It is also possible for the emission-converting material according to the invention to comprise further conversion phosphors besides the compound according to the invention. In this case, the emission-converting material according to the invention comprises a mixture of at least two conversion phosphors, one of which is a compound according to the invention. It is particularly preferred for the at least two conversion phosphors to be phosphors which emit light of different wavelengths which are complementary to one another. Since the compound according to the invention is a yellow-, green- or yellow/green-emitting compound, this is preferably employed in combination with an orange- or red-emitting compound and a blue-emitting LED or with an orange- or red-emitting compound, a blue-emitting compound and a UV-emitting LED. It may thus be preferred for the conversion phosphor according to the invention to be employed in combination with one or more further conversion phosphors in the emission-converting material according to the invention, which then together preferably emit white light.

In the context of this application, blue light denotes light whose emission maximum is between 400 and 459 nm, cyan light denotes light whose emission maximum is between 460 and 505 nm, green light denotes light whose emission maximum is between 506 and 545 nm, yellow light denotes light whose emission maximum is between 546 and 565 nm, orange light denotes light whose emission maximum is between 566 and 600 nm and red light denotes light whose emission maximum is between 601 and 670 nm.

The further conversion phosphor which can be employed together with the compound according to the invention can generally be any possible conversion phosphor. The following, for example, are suitable here: Ba₂SiO₄:Eu²⁺, BaSi₂O₅:Pb²⁺, BaₓSr₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺,Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺,Mn²⁺, Ca₅(PO₄)₃F:Mn²⁺, Caₛ(PO₄)₃F:Sb³⁺, Caₛ(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺,Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺,Pb, CaSiO₃:Pb²⁺, CaSiO₃:Pb²⁺, Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺,Cr, CdS:In, CdS:In, CdS:In,Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂Pr³⁺, Gd₂O₂S:Pr,Ce,F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:Tl, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46 (70%)+P47 (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}:Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺,Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, Sr_{0.3}B₂O₃:Eu²⁺,Cl, β-Sr_{0.3}B₂O₃:Pb²⁺, β-Sr_{0.3}B₂O₃:Pb²⁺,Mn²⁺, α-Sr_{0.3}B₂O₃:Sm²⁺, Sr₆P₅BO₂₀:Eu, Sr₅(PO₄)₃Cl:Eu²⁺, Sr₅(PO₄)₃Cl:Eu²⁺,Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺,Mn²⁺(Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃:Pr³⁺, Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu³⁺, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺,Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBrEu³⁺, Y₂O₃:Ce, Y₂O₃:Er³⁺, Y₂O₃:Eu³⁺(YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺, Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS—CdS:Ag⁺,Cl, ZnS—CdS:Cu,Br, ZnS—CdS:Cu,I, ZnS:Cl, ZnS:Eu²⁺, ZnS:Cu, ZnS:Cu⁺, Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺, Te²⁺, ZnS:P, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn, Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺,Cl or ZnWO₄.

The present invention furthermore relates to the use of the emission-converting material according to the invention in a light source. The light source is particularly preferably an LED, in particular a phosphor-converted LED, pc-LED for short. It is particularly preferred here for the emission-converting material to comprise at least one further conversion phosphor besides the conversion phosphor according to the invention, in particular so that the light source emits white light or light having a certain colour point (colour-on-demand principle). “Colour-on-demand principle” is taken to mean the generation of light of a certain colour point with a pc-LED using one or more conversion phosphors.

The present invention thus furthermore relates to a light source which comprises a primary light source and the emission-converting material.

Here too, it is particularly preferred for the emission-converting material to comprise at least one further conversion phosphor besides the conversion phosphor according to the invention, so that the light source preferably emits white light or light having a certain colour point.

The light source according to the invention is preferably a pc-LED. A pc-LED generally comprises a primary light source and an emission-converting material. The emission-converting material according to the invention may for this purpose either be dispersed in a resin (for example epoxy or silicone resin) or, in the case of suitable size ratios, arranged directly on the primary light source or alternatively remote therefrom, depending on the application (the latter arrangement also includes “remote phosphor technology”).

The primary light source can be a semiconductor chip, a luminescent light source, such as ZnO, a so-called TCO (transparent conducting oxide), a ZnSe- or SiC-based arrangement, an arrangement based on an organic light-emitting layer (OLED) or a plasma or discharge source, most preferably a semiconductor chip. Possible forms of primary light sources of this type are known to the person skilled in the art.

If the primary light source is a semiconductor chip, it is preferably a luminescent indium aluminium gallium nitride (InAlGaN), as is known from the prior art.

For use in light sources, in particular pc-LEDs, the emission-converting material according to the invention can also be converted into any desired outer shapes, such as spherical particles, flakes and structured materials and ceramics. These shapes are summarised under the term “shaped bodies”. Consequently, the shaped bodies are emission-converting shaped bodies.

The invention furthermore relates to a lighting unit which contains at least one light source according to the invention. Lighting units of this type are employed principally in display devices, in particular liquid-crystal display devices (LC displays) with backlighting. The present invention therefore also relates to a display device of this type.

In the lighting unit according to the invention, the optical coupling between the emission-converting material and the primary light source (in particular semiconductor chip) preferably takes place by a light-conducting arrangement. This makes it possible for the primary light source to be installed at a central location and optically coupled to the emission-converting material by means of light-conducting devices, such as, for example, optical fibres. In this way, it is possible to achieve lamps adapted to the lighting wishes, consisting of one or more different conversion phosphors, which may be arranged to form a light screen, and an optical waveguide, which is coupled to the primary light source. This makes it possible to place a strong primary light source at a location which is favourable for electrical installation and, without further electrical cabling, only by laying optical waveguides at any desired locations, to install lamps comprising emission-converting materials, which are coupled to the optical waveguides.

The following examples and figures are intended to illustrate the present invention. However, they should in no way be regarded as limiting.

### DESCRIPTION OF THE FIGURES

FIG. 1: Emission spectra of LuAG:Ce, prepared in accordance with Example 1 without addition of a fluxing agent (curve 1), in accordance with Example 4 with the fluxing agent combination SrCl₂+SiO₂ according to the invention (curve 2), in accordance with Example 2 with AlF₃ as fluxing agent (curve 3) and in accordance with Example 3 with BaF₂ as fluxing agent (curve 4). The LuAG:Ce here still contains ions of the fluxing agent in the lattice structure, depending on the preparation process, i.e., for example, Sr and Si in Example 4 (curve 2).

FIG. 2: Emission spectra of the pc-LEDs from Examples 6 and 7.

### EXAMPLES

### General Procedure for Measurement of the Emission

The powder emission spectra are measured by the following general method: a phosphor powder bed having a depth of 5 mm whose surface has been smoothed using a glass plate is irradiated at a wavelength of 450 nm in the integration sphere of an Edinburgh Instruments FL 920 fluorescence spectrometer with a xenon lamp as excitation light source, and the intensity of the emitted fluorescence radiation is measured in 1 nm steps in a range from 465 nm to 800 nm.

### Example 1

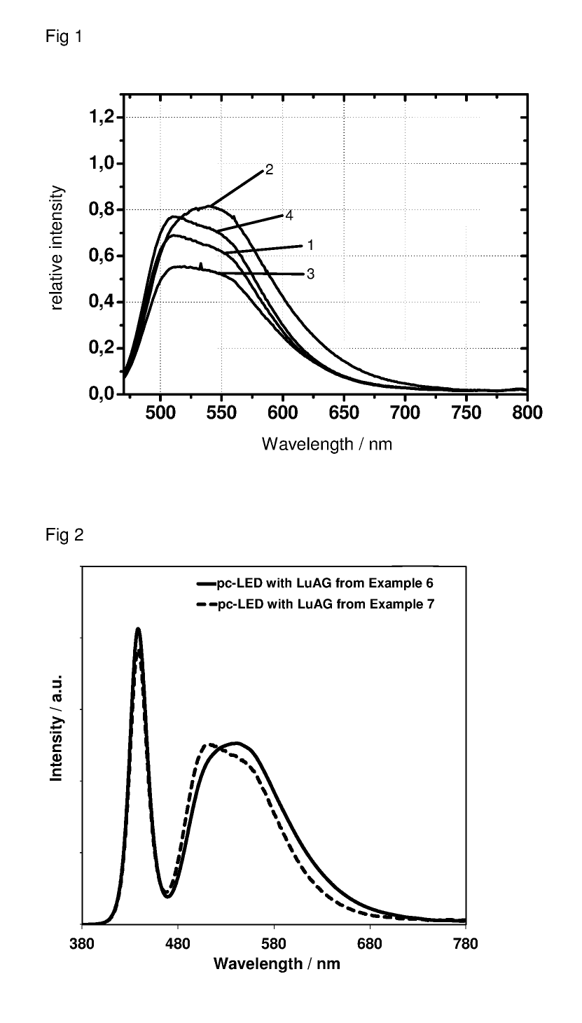

### Preparation of LuAG:Ce without Addition of Fluxing Agent (Curve 1 in FIGS. 1 and 2, Comparative Example)

657.9 g of ammonium hydrogencarbonate are dissolved in 6800 ml of DI water at 25° C. 241.6 g of lutetium chloride hexahydrate, 1.47 g of cerium chloride heptahydrate and 258.7 g of aluminium chloride hexahydrate are dissolved in 1020 ml of DI water. The solution formed is added dropwise over the course of 45 min. to the hydrogencarbonate solution prepared in advance, and the mixture is stirred for a further 60 min. The resultant precipitate is subsequently filtered off with suction and dried at 120° C. in vacuo. The precursor prepared in this way is comminuted on a roller bench for 4 h. The material is subsequently pre-calcined at 1200° C. for 8 h. After the pre-calcination, the product is washed in 1 molar hydrochloric acid. 4 ml of HCl are added per gram of pre-calcined precursor, and the mixture is stirred for 20 min. The solid is filtered off with suction again and rinsed with 12 ml of DI water per g. After re-drying, 50 g of the material are converted into the phosphor for 4 h at a temperature of 1350° C. and under an argon/hydrogen atmosphere.

### Example 2

### Preparation of LuAG:Ce with Addition of AlF₃ (Curve 3 in FIG. 2, Comparative Example)

50 g of the pre-calcined and washed precursor prepared under 1.) are mixed with 0.5 g of AlF₃ and converted into the phosphor for 4 h at a temperature of 1350° C. and under an argon/hydrogen atmosphere.

### Example 3

### Preparation of LuAG:Ce with Addition of BaF₂ (Curve 4 in FIG. 2, Comparative Example)

50 g of the pre-calcined and washed precursor prepared under 1.) are mixed with 1.75 g of BaF₂ and converted into the phosphor for 4 h at a temperature of 1350° C. and under an argon/hydrogen atmosphere.

### Example 4

### Preparation of LuAG:Ce or Lu_{2.88}Ce_{0.02}S_{0.1}Al_{4.9}Si_{0.1}O₁₂ Using the Fluxing Agent Combination According to the Invention (Curve 2 in FIGS. 1 and 2)

363 ml of ethanol, 136 ml of DI water and 54.4 ml of tetraethyl orthosilicate are initially introduced. 84.8 ml of a 25% ammonia solution are added over the course of 30 s with stirring. The SiO₂ suspension formed is stirred for a further 60 min. A pH of 7 is subsequently set by addition of 100 ml of 25% hydrochloric acid. 860.2 g of ammonium hydrogencarbonate are dissolved in 4800 ml of DI water with warming and stirring, the SiO₂ suspension is subsequently added. 207.7 g of lutetium chloride hexahydrate, 4.1 g of cerium chloride heptahydrate, 262.7 g of aluminium chloride hexahydrate and 72.5 g of strontium chloride hexahydrate are dissolved in 960 ml of DI water. The solution formed is added dropwise to the hydrogencarbonate/SiO₂ suspension over the course of 40 minutes, and the mixture is stirred for a further 30 min. The solid is subsequently filtered off with suction and dried at 120° C. in vacuo. The precursor prepared in this way is pre-calcined in air at 1100° C. for 4 h. After the pre-calcination, the product is briefly ground and subsequently converted into the phosphor for 4 h at a temperature of 1350° C. and under an argon/hydrogen atmosphere (90:10 v:v). The product has the composition Lu_{2.88}Ce_{0.02}Sr_{0.1}Al_{4.9}Si_{0.1}O₁₂, where the proportions by weight of the cations were determined by means of ICP-OES.

### Example 5

### General Procedure: Production and Measurement of pcLEDs

A mass of mₚ (in g) of the phosphor shown in the respective LED example is weighed out, mixed with m_{silicone} (in g) of an optically transparent silicone and subsequently mixed in a planetary centrifugal mixer to give a homogeneous mixture, so that the phosphor concentration in the overall mass is cₚ (in % by weight). The silicone/phosphor mixture obtained in this way is applied to the chip of a blue semiconductor LED with the aid of an automatic dispenser and cured with supply of heat. The blue semiconductor LEDs used for the LED characterisation in the present examples have an emission wavelength of 442 nm and are operated at a current strength of 350 mA. The photometric characterisation of the LED is carried out using an Instrument Systems CAS 140 spectrometer and an attached ISP 250 integration sphere. The LED is characterised via determination of the wavelength-dependent spectral power density. The resultant spectrum of the light emitted by the LED is used to calculate the colour point coordinates CIE x and y and the luminous flux Φᵥ (in lm).

### Example 6

### Production of a Pc-LED Using the LuAG:Ce Phosphor According to the Invention from Example 4

| mₚ: | 1.9 | g |
|---|---|---|
| m_{silicone}: | 8.1 | g |
| cₚ: | 19 | wt. % |
| CIE (1931) x: | 0.293 | |
| CIE (1931) y: | 0.370 | |
| Φᵥ: | 69 | lm |

### Example 7

### Production of a Pc-LED Using the LuAG:Ce Phosphor from Example 1 (Comparative Example)

| mₚ: | 1.5 | g |
|---|---|---|
| m_{silicone}: | 8.5 | g |
| cₚ: | 15 | wt. % |
| CIE (1931) x: | 0.271 | |
| CIE (1931) y: | 0.370 | |
| Φᵥ: | 63 | lm |

The phosphor concentrations could not be selected identically in LED Examples 6 and 7 shown above, since similar colour coordinates which can be compared with one another are only obtained at different phosphor concentrations.

As can be seen, the LED from Example 6 has a higher luminous flux Φᵥ (in lm) at comparable colour coordinates and thus has higher efficiency.

1. Compound of the formula (1),
(Lu₁₋ᵥM′ᵥ)_{3-x-z}(EA)_{z}(Al_{1-y}Ga_{y})_{5-z}(Si_{1-w}Ge_{w})_{z}O₁₂:Ce³⁺ₓ formula (1)
where the following applies to the symbols and indices used:
M′ is Y, Tb, Gd or a mixture of these metals;
EA is Ca, Sr, Ba or a mixture of these metals;
0<x<0.50;
0≦y≦0.40;
0.01≦z≦0.5;
0≦w≦1;
0≦v<1.

2. Compound according to claim 1 of the formula (1a), (1b) or (1c),
Lu_{3-x-z}(EA)_{z}(Al_{1-y}Ga_{y})_{5-z}(Si_{1-w}Ge_{w})_{z}O₁₂:Ce³⁺ₓ formula (1a)
(Lu₁₋ᵥM′ᵥ)_{3-x-z}(EA)_{z}Al_{5-z}(Si_{1-w}Ge_{w})_{z}O₁₂:Ce³⁺ₓ formula (1b)
(Lu₁₋ᵥM′ᵥ)_{3-x-z}(EA)_{z}(Al_{1-y}Ga_{y})_{5-z}Si_{z}O₁₂:Ce³⁺ₓ formula (1c)
where the symbols and indices used have the meanings given in claim 1.

3. Compound according to claim 1 of the formula (2a) or (2b),
(Lu₁₋ᵥM′ᵥ)_{3-x-z}(EA)_{z}Al_{5-z}Si_{z}O₁₂:Ce³⁺ₓ formula (2a)
Lu_{3-x-z}(EA)_{z}Al_{5-z}Si_{z}O₁₂:Ce³⁺ₓ formula (2b)
where the symbols and indices used have the meanings given in claim 1.

4. Compound according to claim 1, characterised in that EA is selected from Sr and/or Ba.

5. Compound according to claim 1, characterised in that the following applies to x: 0.01≦x≦0.15.

6. Compound according to claim 1, characterised in that the following applies to z: 0.01≦z≦0.25.

7. Process for the preparation of a cerium-doped garnet, characterised in that the process is carried out via a precursor prepared by wet-chemical methods, and a silicon- or germanium-containing compound and an alkaline-earth metal halide are added.

8. Process according to claim 7, characterised in that the cerium-doped garnet is a compound of the formula (3) or (4),
M₃₋ₓ(Al_{1-y}Ga_{y})₅O₁₂:Ce³⁺ₓ formula (3)
M_{3-x-z}(EA)_{z}(Al_{1-y}Ga_{y})_{5-z}(Si_{1-w}Ge_{w})_{z}O₁₂:Ce³⁺ₓ formula (4)
where the following applies to the symbols and indices used:
M is Lu, Y, Tb, Gd or a mixture of these metals;
EA is Mg, Ca, Sr, Ba or a mixture of these metals;
0<x<0.50;
0≦y≦0.40;
0.01≦z≦0.5;
0≦w<1;
some of the ions M in formula (3) may also be replaced by an alkaline-earth metal selected from Mg, Ca, Sr and/or Ba, and at the same time an equal proportion of Al or Ga may be replaced by Si or Ge.

9. Process according to claim 7, characterised in that the silicon-containing or germanium-containing compound is a silicon dioxide or germanium dioxide suspension or a precursor thereof selected from tetraalkyl orthosilicates, where the alkyl groups have, identically or differently on each occurrence, 1 to 10 C atoms, or silicon halides or tetraalkyl orthogermanates, where the alkyl groups have, identically or differently on each occurrence, 1 to 10 C atoms, or germanium halides.

10. Process according to claim 7, characterised in that the alkaline-earth metal halide employed is CaCl₂, SrCl₂ and/or BaCl₂.

11. Compound obtainable by a process according to claim 7.

12. Emission-converting material comprising a compound according to claim 1 and optionally one or more further conversion phosphors.

13. A method which comprises converting light into light having a longer wavelength with a phosphor or conversion phosphor comprising a compound according to claim 1.

14. Light source comprising a primary light source and at least one compound according to claim 1.

15. Light source according to claim 14, characterised in that the primary light source is a luminescent indium aluminium gallium nitride, in particular of the formula InᵢGaⱼAlₖN, where 0≦i, 0≦j, 0≦k, and i+j+k=1, or a luminescent arrangement based on ZnO, TCO (transparent conducting oxide) or SiC, or a plasma or discharge source.

16. A method which comprises converting light into light having a longer wavelength with a phosphor or conversion phosphor comprising an emission-converting material according to claim 12.

17. Light source comprising a primary light source and at least one emission-converting material according to claim 12.
